(19) United States
(12) Patent Application Publication
(10) Pub. No.: US 2025/0014909 A1
(43) Pub. Date: Jan. 9, 2025

(54) SELECTIVE ETCH USING FLUOROCARBON-BASED DEPOSITION OF A METALLOID OR METAL

(71) Applicant: Lam Research Corporation, Fremont, CA (US)

(72) Inventors: Eric HUDSON, Berkeley, CA (US); Prabhat KUMAR, Fremont, CA (US)

(21) Appl. No.: 18/710,946

(22) PCT Filed: Nov. 28, 2022
(86) PCT No.: PCT/US2022/051098

§ 371 Date: May 16, 2024

Related U.S. Application Data
(60) Provisional application No. 63/284,877, filed on Dec. 1, 2021.

(51) Int. Cl. H01L 21/311; H01L 21/02; H01L 21/033

(52) U.S. Cl. CPC H01L 21/31144; H01L 21/0206; H01L 21/0332; H01L 21/31116

(57) ABSTRACT

A method for selectively etching at least one feature in a silicon oxide region with respect to a lower oxygen containing region is provided. An etch gas is provided comprising a fluorocarbon gas and at least one of a metalloid halide gas or metal halide gas. The etch gas is formed into a plasma. At least one feature is selectively etched in the silicon oxide region with respect to the lower oxygen containing region, while simultaneously forming a metalloid or metal containing hardmask over the lower oxygen containing region.

### CROSS-REFERENCE TO RELATED APPLICATION

This application claims the benefit of priority of U.S. Application No. 63/284,877, filed Dec. 1, 2021, which is incorporated herein by reference for all purposes.

### BACKGROUND

The background description provided here is for the purpose of generally presenting the context of the disclosure. Information described in this background section, as well as aspects of the description that may not otherwise qualify as prior art at the time of filing, are neither expressly nor impliedly admitted as prior art against the present disclosure.

The disclosure relates to methods of forming semiconductor devices on a semiconductor wafer. More specifically, the disclosure relates to the selective etching of silicon oxide (SiO₂) with respect to other materials. In the specification and claims the etching of SiO₂ includes the etching of SiO₂ based materials, such as borophosphosilicate glass (BPSG, a silicon oxide glass doped with boron and phosphorous) or carbon doped silicon oxide, such as SiCOH or other low-k silicon oxide based materials. Such SiO₂ based materials may be other types of doped SiO₂.

The smallest feature dimensions of semiconductor devices are constantly shrinking to follow Moore's law. One of these features is the contact between the 1^{st} metal layer and the silicon layer with gates and source/drains (S/D). Such features are typically prepared by a process called self-aligned contact (SAC). In a SAC etch, SiO₂ is etched to form a hole or a trench. Later, the hole or trench is filled with a contact metal. A selective SiO₂ etch is employed to selectively etch SiO₂ with respect to a spacer material. The spacer material is typically a lower oxygen containing silicon material such as silicon nitride, silicon oxy-nitride, or silicon oxy-carbon-nitride. Many selective etch processes are not selective enough. As a result, too much of the spacer material or corners of the spacer material may be etched increasing electric leakage and device failure rates.

### SUMMARY

To achieve the foregoing and in accordance with the purpose of the present disclosure, a method for selectively etching at least one feature in a silicon oxide region with respect to a lower oxygen containing region is provided. An etch gas is provided comprising a fluorocarbon gas and at least one of a metalloid halide gas or metal halide gas. The etch gas is formed into a plasma. At least one feature is selectively etched in the silicon oxide region with respect to the lower oxygen containing region, while simultaneously forming a metalloid or metal containing hardmask over the lower oxygen containing region.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of an embodiment.

FIGS. 2A-E are schematic cross-sectional views of structures processed according to an embodiment.

FIG. 3 is a more detailed flow chart of a selective etch of the silicon oxide region while depositing a metalloid or metal containing hardmask.

FIG. 4 is a high level flow chart of another embodiment.

FIG. 5 is a schematic view of a etch chamber that may be used in an embodiment.

FIG. 6 is a schematic view of a computer system that may be used in practicing an embodiment.

### DETAILED DESCRIPTION OF THE EXEMPLARY EMBODIMENTS

The present disclosure will now be described in detail with reference to a few exemplary embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

The hole or trench of the contacts needs to be very accurately placed in respective to the underlying gate and S/D. Current photolithography tools can only partially meet the placement requirement of the contacts. Therefore, the contact etch can expose the spacer around the gate. Such exposure often leads to corner loss of the space material resulting in an electric leakage.

The selective SiO₂ etch can be achieved by the protection of the spacer against an etch using the selective deposition of a carbon-based polymer on the spacer material. However, the lateral dimensions of the hole and trench in the 5 nanometers (nm) node and below can be smaller than 10 nm. More typically, such features may be in the of 5-15 nm range. The aspect ratio can be larger than 6:1. In some embodiments, the aspect ratio may range from 6:1 to 12:1. In addition, the use of a carbon-based polymer mask has a limited etch resistance. The limited etch resistance requires deposition of a thick mask to protect the spacer during the SiO₂ etch. Placing thick polymer material on the spacer can clog up and/or pinch-off the contact and block any further etch. This blocked etch would result in an electrical open contact, causing a device failure. Additionally, thick polymer material tends to have deposit different quantities in different parts of the pattern layout, depending on the local shading of the features. This effect, which can be described as pattern loading, leads to undesirable variation in the final results of the etch including the critical dimension (CD) of the trench or hole.

The process and apparatus of this disclosure enable the selective deposition of a metalloid or metal containing mask such as metal carbide on the spacer material during the etch process. This mask is not formed by the initial photolithography but in-situ during the etch process. Due to the higher etch selectivity of a metalloid or metal containing mask compared to the traditional carbon-based polymer mask, a thinner, less than 5 nm hardmask, is sufficient. This metalloid or metal containing hardmask can prevent the corner loss of the spacer while avoiding the pinch-off issues of the traditional polymer material. This thin metalloid or metal containing hardmask may also introduce low variability from pattern loading.

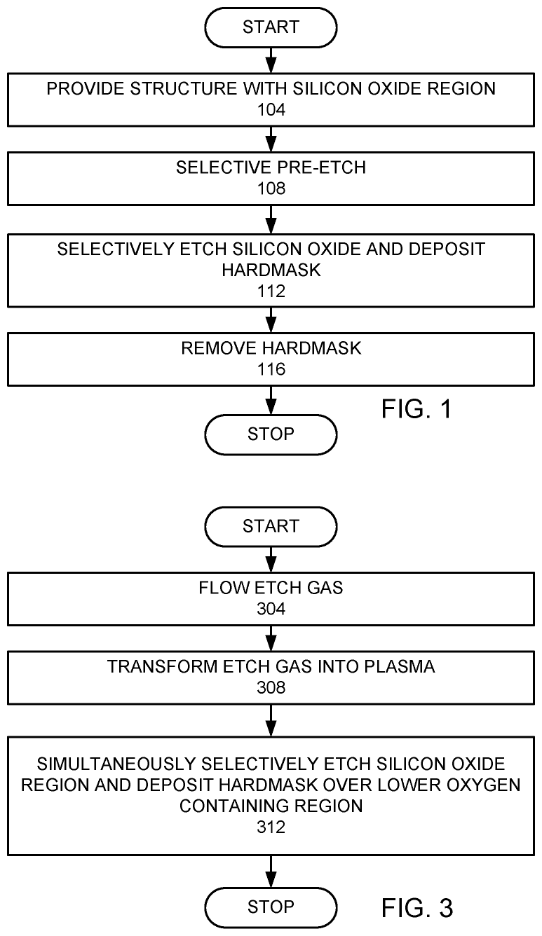

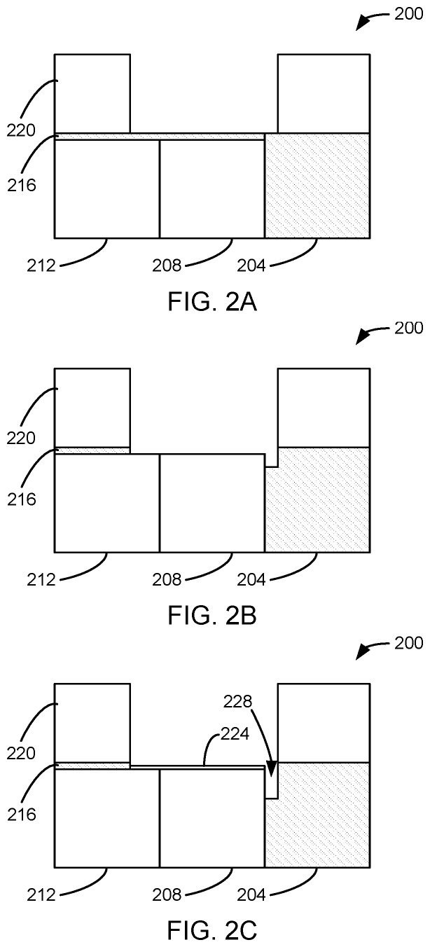

In order to facilitate understanding, FIG. 1 is a high level flow chart of an embodiment. A structure with a silicon oxide region is provided (step 104). FIG. 2A is a schematic cross-sectional view of part of a structure 200 with a silicon oxide region 204. In this example, the structure 200 also has a silicon oxycarbonitride (SiOCN) region 208, and a silicon (Si) region 212. The silicon region 212 may be crystalline or polycrystalline, or amorphous silicon. The SiOCN material may include silicon oxynitride (SiON), silicon oxycarbide (SiOC), silicon carbonitride (SiCN), organosilicon oxide (SiOCHₓ) (back end of line (BEOL) low-k), silicon nitride (SiN), or silicon carbide (SiC). The SiOCN region 208 and the Si region 212 are designated as lower oxygen containing regions since they have a lower concentration of oxygen than the silicon oxide regions 204. In this embodiment, a native silicon oxide layer 216 naturally forms over the SiOCN region 208 and the silicon region 212, when the SiOCN region 208 and the silicon region are exposed to air. In an alternative embodiment, layer 216 is a deposited silicon oxide layer which covers the SiOCN region 208 and the silicon region 212 after filling the silicon oxide region 204. A photolithographic mask 220 of patterned photoresist is formed over the structure 200, as shown. In an alternative embodiment, the mask 220 may be a hardmask prepared by prior lithography and etch processes. The mask 220 may be a spin on carbon material, silicon, silicon nitride or may be other materials that allow silicon oxide to be selectively etched.

After the structure is provided, a selective pre-etch is provided (step 108) that selectively etches the silicon oxide region 204 and the native silicon oxide layer 216 not covered by the photolithographic mask 220. In this embodiment, the silicon oxide region 204 is selectively etched using an atomic layer etch (ALE). In this embodiment, the ALE provides a reactant gas of hexafluoro-1,3-butadiene (C₄F₆). The C₄F₆ forms a polymer deposition layer over the silicon oxide region 204 and the native silicon oxide layer 216. The reactant gas is purged, and an activation gas of argon (Ar) is provided. The Ar activates the deposition layer causing deposited fluorine to selectively etch the silicon oxide region 204 and the native silicon oxide layer 216. The ALE process of a selective deposition and selective etch steps may be repeated for a plurality of cycles. FIG. 2B is a cross-sectional view of the structure 200 after the selective pre-etch (step 108) is complete. In this example, the silicon oxide region 204 not covered by the photolithographic mask 220 is partially etched and the native silicon oxide layer 216 not covered by the photolithographic mask 220 has been etched away. The selective deposition of polymer and selectively etching the silicon oxide region 204 may be repeated, until the silicon oxide region 204 is sufficiently etched and the native silicon oxide layer 216 is removed. Such an etch process selectively etches the silicon oxide region 204. However, the selectivity is not high enough. Some of the SiOCN region 208 and Si region 212 is also etched away. Therefore, this etch is only used for a pre-etch process in this embodiment. In some embodiments, the pre-etch process is not used.

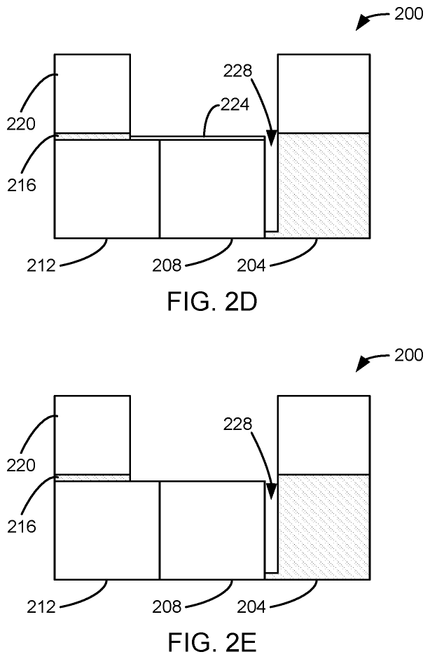

After the selective pre-etch is completed (step 108), a selective etch of the silicon oxide region 204 is provided while depositing a metalloid or metal containing hardmask (step 112). FIG. 3 is a more detailed flow chart of a selective etch of the silicon oxide region 204 while depositing a metalloid or metal containing hardmask (step 112). In such an embodiment, an etch gas comprising a fluorocarbon gas and at least one of a metalloid halide gas or metal halide gas is provided (step 304). In this embodiment, the etch gas comprises hexafluorobutadiene (C₄F₆), tungsten hexafluoride (WF₆), oxygen (O₂), and argon (Ar). In this embodiment, the etch gas is hydrogen free. The etch gas is provided (step 304) by flowing the etch gas into a plasma processing chamber. While the etch gas is flowed into the plasma processing chamber, radio frequency power is provided to transform the etch gas into a plasma (step 308). In an example, a chamber pressure of 1-500 mTorr is provided. The etch gas comprises 0.5-60 sccm C₄F₆, 0.5-60 sccm WF₆, oxygen 0.5-60 sccm, and 50-2000 sccm Ar. In an embodiment, a substrate or chuck temperature in the range of 30° C. to 150° C. is provided. In other embodiments, a substrate or chuck temperature in the range of 30° C. to 210° C. is provided. In other embodiments, the substrate or chuck is maintained at a temperature of no more than about 210° C. In other embodiments, the substrate or chuck is maintained at a temperature of no more than about 300° C. To form the etch gas into a plasma and provide bias, 20-1000 W (capacitively coupled plasma (CCP) and bias) is provided at radio frequencies such as one or more of 13.56 megahertz (MHz), 60 MHz, 27 MHz, 2 MHz, 1 MHZ, 400 kilohertz (kHz), or combinations thereof. The plasma simultaneously selectively etches the silicon oxide region 204 with respect to the lower oxygen containing region and forms a metalloid or metal containing hardmask over the lower oxygen containing region (step 312). The selective etch also highly selectively etches the silicon oxide region 204 with respect to the photolithographic mask 220. In this embodiment, the selective etch is a hydrogen free selective etch.

FIG. 2C is a cross-sectional view of the structure 200 after the selective etch of the silicon oxide region 204 while depositing a metalloid or metal containing hardmask (step 112) partially etches a feature 228 in the silicon oxide region 204. Fluorine and carbon in the plasma etch the silicon oxide region 204. Carbon and the metal in the plasma selectively deposit metalloid or metal containing hardmask 224 on the SiOCN region 208 and the Si region 212. The plasma conditions can reduce the metalloid or metal containing precursor or its plasma fragment to deposit the metalloid or metal containing hardmask 224 selectively on the SiOCN region 208 and the Si region 212. Alternatively, carbon in the plasma reacts with the metalloid or metal containing precursor or its fragment to form the metalloid or metal containing hardmask 224 on the SiOCN region 208 and the Si region 212. The oxygen containing component of the silicon oxide region 204 maintains the etch of the silicon oxide region 204 by preventing or minimizing the deposition of the carbon containing layer and/or the metalloid or metal containing hardmask 224 on the silicon oxide region 204. In this embodiment, the metalloid or metal containing hardmask 224 is a tungsten carbide hardmask. The metalloid or metal containing hardmask 224 prevents or minimizes the etching of the lower oxygen containing regions, while the silicon oxide region 204 is etched. As a result, the etch selectivity may approach infinity.

FIG. 2D is a cross-sectional view of the structure 200 after the selective etch of the silicon oxide region 204 has been sufficiently etched. Since the metalloid or metal containing hardmask 224 is continuously deposited during the etching of the silicon oxide region 204 and since the metalloid or metal containing hardmask 224 is resistant to the etch, the lower oxygen containing regions are not etched or are etched only a small and acceptable amount. In this embodiment, when the etching of the silicon oxide region 204 is complete, the metalloid or metal containing hardmask 224 remains.

After the etching of the silicon oxide region 204 is complete, the metalloid or metal containing hardmask 224 is removed. In this embodiment, a wet clean is used to remove the metalloid or metal containing hardmask 224. In the embodiment, an aqueous solution of ammonia (NH₃) and hydrogen peroxide (H₂O₂) is used to selectively remove the metalloid or metal containing hardmask 224 with respect to the silicon oxide region 204. FIG. 2E is a cross-sectional view of the structure 200 after the metalloid or metal containing hardmask 224 has been removed.

This embodiment provides a highly selective etch of silicon oxide with respect to lower oxygen containing regions. In various embodiments, the depth to width aspect ratio of the feature 228 etched in the silicon oxide region 204 is at least 6:1. For example, the feature 228 has a depth to width aspect ratio is between 6:1 and 12:1. In this example, the feature 228 has a width of less than 10 nm. In various embodiments, the feature 228 has a width of between 6 to 15 nm. The use of the metalloid or metal containing hardmask 224 prevents or reduces the etching of the SiOCN region 208, so that corner loss of the SiOCN region 208 is prevented or reduced. In addition, since the metalloid or metal containing hardmask 224 is kept thin, clog up and pinch-off of the feature 228 is prevented. In some embodiments, the partial etch of the pre-etch step (step 108) provides a geometry, where the silicon oxide region 204 is recessed. In some embodiments, the recessed initial geometry of the silicon oxide region 204 allows for more selective deposition of the metalloid or metal containing hardmask 224 and selective etch of the silicon oxide region 204.

The etch resistance of the metalloid or metal containing hardmask 224 is high because a metalloid or metal containing material such as metal carbide has a very high melting and boiling point. In other embodiments, other metalloid or metal containing hardmasks made of metal nitride, metal boride, or metal silicide can be used instead of metal carbide or together with metal carbide as long as the metalloid or metal containing hardmasks have a high etch resistance. Since this embodiment provides a metalloid or metal containing hardmask 224 with a high etch resistance, the mask thickness may be less than 5 nm. This thin hardmask enables the etch of very narrow features <15 nm by avoiding the clogging risk.

In alternative embodiments, near the end of the etching of the silicon oxide region 204, the flow of the metalloid or metal containing precursor is reduced or stopped so that the deposition of the metalloid or metal containing hardmask 224 is reduced or stopped. In one embodiment, at the end of the etch of the silicon oxide region 204 the metalloid or metal containing hardmask 224 is etched away so that removal of the metalloid or metal containing hardmask (step 116) is not needed. In another embodiment, a dry etch is used to selectively remove the metalloid or metal containing hardmask (step 116) with respect to the silicon oxide region 204.

In another embodiment, the metalloid or metal containing precursor and a halogen containing component is molybdenum hexafluoride (MoF₆). In other embodiments, the metalloid or metal containing precursor may be other metalloid halides or metal halides. In such embodiments, metalloids, such as boron (B), silicon (Si), germanium (Ge), antimony (Sb), or metals, such as tin (Sn), titanium (Ti), zirconium (Zr), hafnium (Hf), vanadium (V), niobium (Nb), tantalum (Ta), aluminum (Al), gallium (Ga), indium (In), iron (Fe), ruthenium (Ru), rhenium (Re), tungsten (W), molybdenum (Mo), and bismuth (Bi), may be used if a metalloid or metal halogen exists to allow the metalloid or metal halide to be flowed as a gas or vapor. In some embodiments, a liquid metal halide may be heated to form a metal halide vapor. In some embodiments, a solid metal halide may be heated to sublime to form a metal halide vapor. Metalloid or metal bromides may be used in other embodiments. In other embodiments, the precursor may be metalloid or metal oxyhalides.

In other embodiments, other lower oxygen regions may be used in place of the lower oxygen silicon containing regions. For example, silicon germanium (SiGe), germanium (Ge), elemental metal or metal nitrides may form the lower oxygen regions and may be protected, so that SiO₂ may be selectively etched with respect to these materials.

In some embodiments, the etch gas further comprises an oxygen containing component. In some embodiments, the oxygen containing component comprises at least one of oxygen (O₂), ozone (O₃), carbon dioxide (CO₂), carbon monoxide (CO), nitric oxide (NO), nitrogen dioxide (NO₂), nitrous oxide (N₂O), sulfur dioxide (SO₂), sulfur trioxide (SO₃), and carbonyl sulfide (COS). In various embodiments, the etch gas further comprises an inert gas. In some embodiments, the inert gas is selected from the group consisting of nitrogen, helium, argon, krypton, xenon, and neon. In various embodiments, a plasma is formed at a pressure of 1-500 millitorr with a power of 20-1000 Watts at radio frequencies such as one or more of 13.56 megahertz (MHz), 60 MHz, 27 MHz, 2 MHz, 1 MHz, 400 kilohertz (kHz), or combinations thereof.

In various embodiments, the selective pre-etch (step 108) allows the removal of any native silicon oxide layer 216. If the lower oxygen containing region does not form a native oxide layer, the selective pre-etch (step 108) may not be needed. The hardmask may be selectively deposited without the selective pre-etch (step 108).

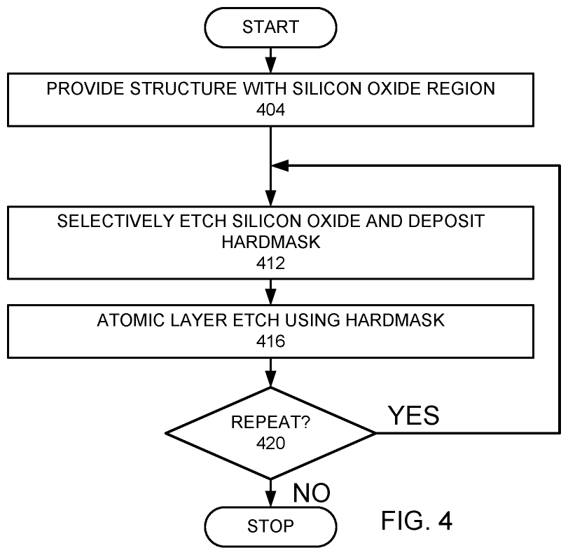

Another embodiment is shown by the flow chart shown in FIG. 4. In such an embodiment, a structure is provided with a silicon oxide region (step 404). A selective etch of the silicon oxide region is provided while depositing a metalloid or metal containing hardmask (step 412).

In this embodiment, after the silicon oxide region has been partially etched leaving a metalloid or metal containing hardmask, the silicon oxide region is further or additionally etched by an atomic layer etch (ALE) process utilizing the metalloid or metal containing hard mask (step 416). In this embodiment, the ALE provides a reactant gas of C₄F₆. The C₄F₆ forms a polymer deposition layer over the silicon oxide region and the metalloid or metal containing hardmask. The reactant gas is purged, and an activation gas of Ar is provided. The Ar activates the deposition layer causing deposited fluorine to selectively etch the silicon oxide region with respect to the metalloid or metal containing hard mask. The ALE process of a selective deposition and selective etch steps may be repeated for a plurality of cycles.

Since the ALE process does not deposit the metalloid or metal containing hardmask, the metalloid or metal containing hardmask may be consumed during the ALE process. If the metalloid or metal containing hardmask is sufficiently consumed before etching of the silicon oxide region is completed, the ALE process (step 416) may be stopped and the selective etch of the silicon oxide region while depositing a metalloid or metal containing hardmask (step 412) may be repeated (step 420) in order to replenish the metalloid or metal containing hardmask. After the metalloid or metal hardmask has been replenished, the selective etching of the silicon oxide region while depositing a metalloid or metal containing hardmask (step 412) is stopped. The ALE process may be used to further etch the silicon oxide region (step 416). The steps of selectively etching the silicon oxide while depositing the metalloid or metal containing hardmask (step 412) and the ALE using the metalloid or metal containing hardmask (step 416) may be cyclically repeated until the feature in the silicon oxide region is sufficiently etched. Once the feature in the silicon oxide region is sufficiently etched the cyclical process may be stopped. Since the ALE process (step 416) consumes the metalloid or metal hardmask in this embodiment, a separate metal or metalloid hardmask removal step is not needed.

In some embodiments, the deposition of the hardmask and etching may be done in separate sequential steps. However, simultaneously depositing the hardmask and etching in a single continuous step may provide a faster process.

It has been unexpectedly found that providing a hydrogen free selective etch of the silicon oxide region while depositing a metalloid or metal containing hardmask reduces pattern loading, while providing sufficient protection of corners of regions with lower concentration of oxygen. Preventing pattern loading provides the ability to achieve similar final top CD for a range of differently shaped features within a single die. In practice, there is typically smaller CD in the more exposed features and larger CD in the features which are locally shaded, e.g., by a cut mask. Providing a hydrogen free selective etch provides a CD that is less dependent on shading. Higher aspect ratio features generally have more shading. So, providing a process where CD is less dependent on shading provides an improved process for higher aspect ratio features. Without wishing to be bound by theory, it is proposed that a process gas which comprises the hydrogen element in one or more gases tends to produce carbon-bearing polymer precursors with a higher sticking coefficient. Neutral deposition from these precursors tends to have more feature-dependent and aspect-ratio dependent effects. Conversely, a hydrogen free process tends to have carbon-bearing precursors with a lower sticking coefficient, with less resultant loading effects. Using a fluorocarbon instead of a hydrofluorocarbon or hydrocarbon helps to provide a hydrogen free process. In other embodiments, other fluorocarbons (CₓF_{y}), such as C₄F₆, perfluorocyclobutane (c-C₄F₈), octafluorocyclopentene (c-C₅F₈), tetrafluoroethylene (C₂F₄), carbon tetrafluoride (CF₄), octofluoropropane (C₃F₈), and hexafluoroethane (C₂F₆) may be used. Some embodiments allow for thinner passivation layers that help to control breadloafing issues in more exposed features. In some embodiments, 59 nm of SiO may be etched with less than 3 nm of SiN etched.

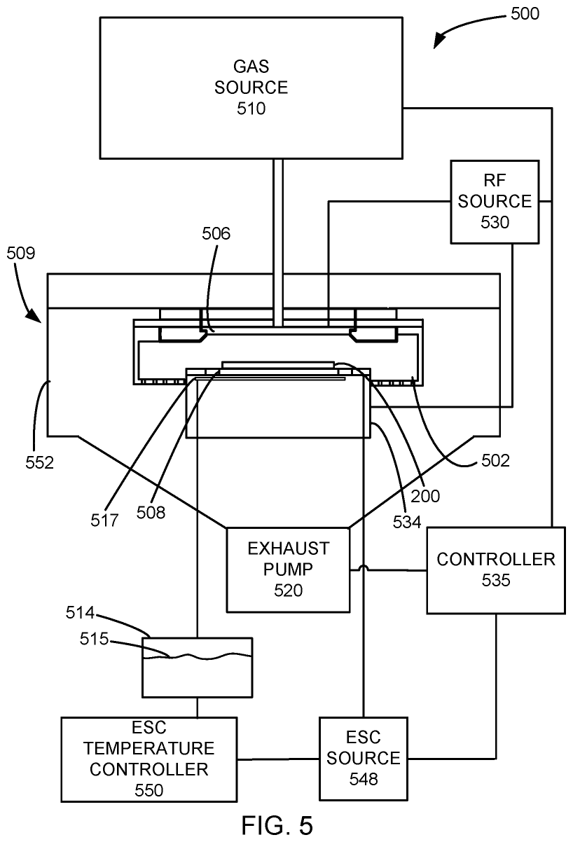

FIG. 5 is a schematic view of an etch reactor system 500 that may be used in an embodiment. In one or more embodiments, an etch reactor system 500 comprises a gas distribution plate 506 providing a gas inlet and an electrostatic chuck (ESC) 508, within an etch chamber 509, enclosed by a chamber wall 552. Within the etch chamber 509, the structure 200 is positioned over the ESC 508. The ESC 508 may provide a bias from the ESC source 548. An etch gas source 510 is connected to the etch chamber 509 through the gas distribution plate 506. An ESC temperature controller 550 is connected to the ESC 508. A radio frequency (RF) source 530 provides RF power to a lower electrode and/or an upper electrode, which in this embodiment are the ESC 508 and the gas distribution plate 506, respectively. In an exemplary embodiment, 60 megahertz (MHz), and optionally, 2 MHZ, 27 MHz power sources make up the RF source 530 and the ESC source 548. In this embodiment, the upper electrode is grounded. In this embodiment, one generator is provided for each frequency. In other embodiments, the generators may be in separate RF sources, or separate RF generators may be connected to different electrodes. For example, the upper electrode may have inner and outer electrodes connected to different RF sources. Other arrangements of RF sources and electrodes may be used in other embodiments. A controller 535 is controllably connected to the RF source 530, the ESC source 548, an exhaust pump 520, and the etch gas source 510. An example of such an etch chamber is the Flex™ etch system manufactured by Lam Research Corporation of Fremont, CA. In various embodiments, the process chamber can be a CCP (capacitively coupled plasma) reactor or an ICP (inductively coupled plasma) reactor.

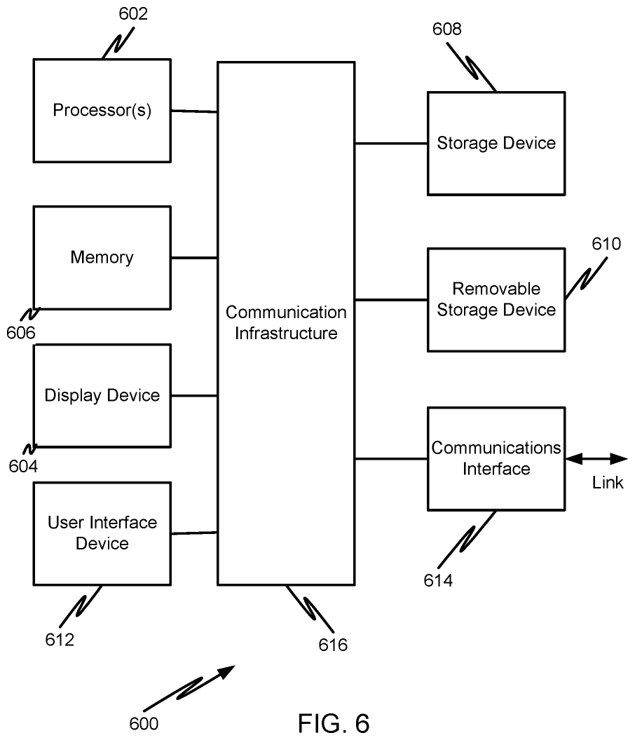

To provide an example of a controller 535 in an embodiment, FIG. 6 is a high level block diagram showing a computer system 600 that is suitable for implementing the controller 535 used in embodiments. The computer system may have many physical forms ranging from an integrated circuit, a printed circuit board, and a small handheld device, up to a huge supercomputer. The computer system 600 includes one or more processors 602, and further can include an electronic display device 604 (for displaying graphics, text, and other data), a main memory 606 (e.g., random access memory (RAM)), storage device 608 (e.g., hard disk drive), removable storage device 610 (e.g., optical disk drive), user interface devices 612 (e.g., keyboards, touch screens, keypads, mice or other pointing devices, etc.), and a communication interface 614 (e.g., wireless network interface). The communication interface 614 allows software and data to be transferred between the computer system 600 and external devices via a link. The system may also include a communications infrastructure 616 (e.g., a communications bus, cross-over bar, or network) connected to the aforementioned devices/modules.

Information transferred via communications interface 614 may be in the form of signals such as electronic, electromagnetic, optical, or other signals capable of being received by communications interface 614, via a communication link that carries signals and may be implemented using wire or cable, fiber optics, a phone line, a cellular phone link, a radio frequency link, and/or other communication channels. With such a communications interface, it is contemplated that the one or more processors 602 might receive information from a network or might output information to the network in the course of performing the above-described method steps. Furthermore, method embodiments may execute solely upon the processors or may execute over a network, such as the Internet, in conjunction with remote processors that share a portion of the processing.

The term “non-transient computer readable medium” is used generally to refer to media such as main memory, secondary memory, removable storage, and storage devices, such as hard disks, flash memory, disk drive memory, CD-ROM, and other forms of persistent memory, and shall not be construed to cover transitory subject matter, such as carrier waves or signals. Examples of computer code include machine code, such as one produced by a compiler, and files containing higher level code that are executed by a computer using an interpreter. Computer readable media may also be computer code transmitted by a computer data signal embodied in a carrier wave and representing a sequence of instructions that are executable by a processor.

While this disclosure has been described in terms of several exemplary embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure. As used herein, the phrase “A, B, or C” should be construed to mean a logical (“A OR B OR C”), using a non-exclusive logical “OR,” and should not be construed to mean ‘only one of A or B or C. Each step within a process may be an optional step and is not required. Different embodiments may have one or more steps removed or may provide steps in a different order. In addition, various embodiments may provide different steps simultaneously instead of sequentially.

What is claimed is:

1. A method for selectively etching at least one feature in a silicon oxide region with respect to a lower oxygen containing region, comprising:
providing an etch gas comprising a fluorocarbon gas and at least one of a metalloid halide gas or metal halide gas;
forming the etch gas into a plasma; and
simultaneously selectively etching at least one feature in the silicon oxide region with respect to the lower oxygen containing region and forming a metalloid or metal containing hardmask over the lower oxygen containing region.

2. The method, as recited in claim 1, wherein the etch gas is hydrogen free.

3. The method, as recited in claim 1, wherein the fluorocarbon gas comprises CₓF_{y}.

4. The method, as recited in claim 1, wherein the fluorocarbon gas comprises at least one of C₄F₆, c-C₄F₈, c-C₅F₈, C₂F₄, CF₄, C₄F₈, C₃F₈, and C₂F₆.

5. The method, as recited in claim 1, wherein the etch gas further comprises an oxygen containing component comprising at least one of O₂, O₃, CO₂, CO, NO, NO₂, N₂O, SO₂, SO₃, and COS).

6. The method, as recited in claim 1, wherein the etch gas further comprises an inert gas from the group consisting of nitrogen, helium, argon, krypton, xenon, and neon.

7. The method, as recited in claim 1, further comprising providing a selective pre-etch before providing the etch gas, wherein the selective pre-etch selectively and partially etches the at least one feature of the silicon oxide region with respect to the lower oxygen containing region without forming a metalloid or metal containing hardmask.

8. The method, as recited in claim 1, wherein the metalloid halide gas or metal halide gas comprises at least one of WF₆ and MoF₆ gas.

9. The method, as recited in claim 1, wherein metalloid halide gas or metal halide gas comprises at least one of silicon (Si), germanium (Ge), tin (Sn), titanium (Ti), zirconium (Zr), hafnium (Hf), vanadium (V), niobium (Nb), tantalum (Ta), boron (B), aluminum (Al), gallium (Ga), indium (In), iron (Fe), ruthenium (Ru), rhenium (Re), antimony (Sb), tungsten (W), molybdenum (Mo), or bismuth (Bi).

10. The method, as recited in claim 1, where the plasma is formed at a pressure of 1-500 millitorr with a power of 20-1000 Watts.

11. The method, as recited in claim 1, further comprising providing an atomic layer etch of the at least one feature in the silicon oxide region after the selectively etching the at least one feature in the silicon oxide region with respect to the lower oxygen containing, wherein the atomic layer etch uses the metalloid or metal containing hardmask to reduce etching of the lower oxygen containing region.

12. The method, as recited in claim 1, wherein the at least one feature has a width of less than 15 nm and a depth to width aspect ratio of at least 6:1.

13. The method, as recited in claim 1, further comprising providing an additional etch of the at least one feature in the silicon oxide region after the selectively etching the at least one feature in the silicon oxide region with respect to the lower oxygen containing region, wherein the additional etch uses metalloid or metal containing hardmask as a mask and without further depositing the metalloid or metal containing hardmask.

14. The method, as recited in claim 13, further comprising removing the metalloid or metal containing hardmask after the additional etch of the at least one feature.

15. The method, as recited in claim 14, wherein the removing the metalloid or metal containing hardmask comprises a wet clean.

16. The method, as recited in claim 1, further comprising providing a temperature of no more than 300° C.
